(19) United States
(12) Patent Application Publication
(10) Pub. No.: US 2026/0066237 A1
(43) Pub. Date: Mar. 5, 2026

(54) PLASMA ETCHING APPARATUS AND PLASMA ETCHING METHOD

(71) Applicant: Tokyo Electron Limited, Tokyo (JP)

(72) Inventors: Norihiko AMIKURA, Miyagi (JP); Satoru NAKAMURA, Miyagi (JP); Manabu ISHIKAWA, Miyagi (JP); Kentaro ISHII, Miyagi (JP); Yusuke SHIMIZU, Miyagi (JP); Atsushi SAWACHI, Miyagi (JP)

(73) Assignee: Tokyo Electron Limited, Tokyo (JP)

(21) Appl. No.: 19/382,395

(22) Filed: Nov. 7, 2025

Related U.S. Application Data
(63) Continuation of application No. PCT/JP2024/036692, filed on Oct. 15, 2024.

(30) Foreign Application Priority Data
Oct. 24, 2023 (JP) 2023-182263

(51) Int. Cl. H01J 37/32

(52) U.S. Cl. CPC H01J 37/32449; H01J 37/32834; H01J 2237/3346

(57) ABSTRACT

A plasma etching apparatus includes a chamber, a gas supply that supplies a gas into the chamber, and circuitry. The gas supply includes a gas box that supplies the gas, a gas-diffusion compartment that diffuses the gas from the gas box inside the gas-diffusion compartment and introduces the gas into the chamber, and an exhaust that discharges the gas in the gas-diffusion compartment. The circuitry is configured to control operations including (a) supplying a first gas from the gas box at a first flow rate to generate plasma in the chamber and (b) stopping supply of the first gas from the gas box, supplying a second gas from the gas box at a second flow rate, and performing gas discharge from the gas-diffusion compartment. (b) includes maintaining the gas-diffusion compartment at a pressure at which the plasma is maintained in the chamber.

### CROSS-REFERENCE TO RELATED APPLICATIONS

This application is a bypass continuation application of international application No. PCT/JP2024/036692 having an international filing date of Oct. 15, 2024 and designating the United States, the international application being based upon and claiming the benefit of priority from Japanese Patent Application No. 2023-182263, filed on Oct. 24, 2023, the entire contents of each are incorporated herein by reference.

### FIELD

The disclosure relates to a plasma etching apparatus and a plasma etching method.

### BACKGROUND

Patent Literature 1 describes a method for selectively etching a silicon oxide film on a target substrate including a silicon nitride film and the silicon oxide film on a surface of the substrate. The method includes intermittently exposing the target substrate to a process gas multiple times in a vacuum atmosphere. The process gas is at least one of a process gas containing a hydrogen fluoride gas and an ammonia gas or a process gas containing a compound containing nitrogen, hydrogen, and fluorine.

### CITATION LIST

### Patent Literature

Patent Literature 1: Japanese Unexamined Patent Application Publication No. 2015-144249

### BRIEF SUMMARY

### Technical Problem

One or more aspects of the disclosure are directed to a technique for switching gases appropriately during plasma etching.

### Solution to Problem

A plasma etching apparatus according to one aspect of the disclosure includes a chamber, a gas supply that supplies a gas into the chamber, and circuitry. The gas supply includes a gas box that supplies the gas, a gas-diffusion compartment that diffuses the gas from the gas box inside the gas-diffusion compartment and introduces the gas into the chamber, and an exhaust that discharges the gas in the gas-diffusion compartment. The circuitry is configured to control operations including (a) supplying a first gas from the gas box at a first flow rate to generate plasma in the chamber and (b) stopping supply of the first gas from the gas box, supplying a second gas from the gas box at a second flow rate, and performing gas discharge from the gas-diffusion compartment. (b) includes maintaining the gas-diffusion compartment at a pressure higher than or equal to a threshold predetermined based on a plasma processing condition as a pressure at which the plasma is maintained in the chamber.

### Advantageous Effects

The technique according to the above aspect of the disclosure allows switching gases appropriately during plasma etching.

### BRIEF DESCRIPTION OF DRAWINGS

FIG. 1 is a diagram of a plasma etching system according to an embodiment, describing an example structure.

FIG. 2 is a cross-sectional view of a plasma etching apparatus according to the embodiment, showing an example structure.

FIG. 3 is a schematic diagram of a gas supply in a first embodiment, showing an example structure.

FIG. 4 is a schematic diagram of an exhaust, showing an example structure.

FIG. 5 is a schematic diagram of the exhaust, showing another example structure.

FIG. 6 is a sequence chart of flow rate control with a gas supply method.

FIG. 7 is a graph showing the pressure in gas-diffusion compartments used with the gas supply method.

FIG. 8 is a sequence chart of flow rate control with a modification of the gas supply method.

FIG. 9 is a schematic diagram of a gas supply in a second embodiment, showing an example structure.

FIG. 10 is a sequence chart of flow rate control with a gas supply method.

FIG. 11 is a graph showing the pressure in a gas-diffusion compartment and a chamber used with the gas supply method.

FIG. 12 is a diagram including a sequence chart of flow rate control with a gas supply method in a comparative example and a graph showing pressure values of a gas-diffusion compartment and a chamber.

### DETAILED DESCRIPTION

Manufacturing processes of semiconductor devices for plasma etching include supplying an intended process gas into a process module accommodating a semiconductor wafer (hereafter referred to as a substrate) and etching the substrate with plasma generated from the process gas.

The substrate to be processed by the plasma etching includes multiple layers with different etching selectivity stacked on one another on a surface of the substrate. To process such a substrate, process gases with high selectivity to the respective layers may be supplied sequentially. More specifically, one process gas may be supplied to etch one layer, and then another process gas may be supplied subsequently to etch another layer.

Patent Literature 1 describes a method for selectively etching a silicon oxide film on a target substrate including a silicon nitride film and the silicon oxide film on a surface of the substrate. The method includes intermittently exposing the target substrate to a process gas multiple times in a vacuum atmosphere. The process gas is at least one of a process gas containing a hydrogen fluoride gas and an ammonia gas or a process gas containing a compound containing nitrogen, hydrogen, and fluorine.

To discharge one process gas and subsequently supply another process gas, an exhaust device connected to the chamber may be used to perform gas discharge from a gas-diffusion compartment through a shower head. In such a case, the flow of the process gas through a gas guide unit in the shower head can be a limiting factor, disabling rapid gas discharge from the gas-diffusion compartment.

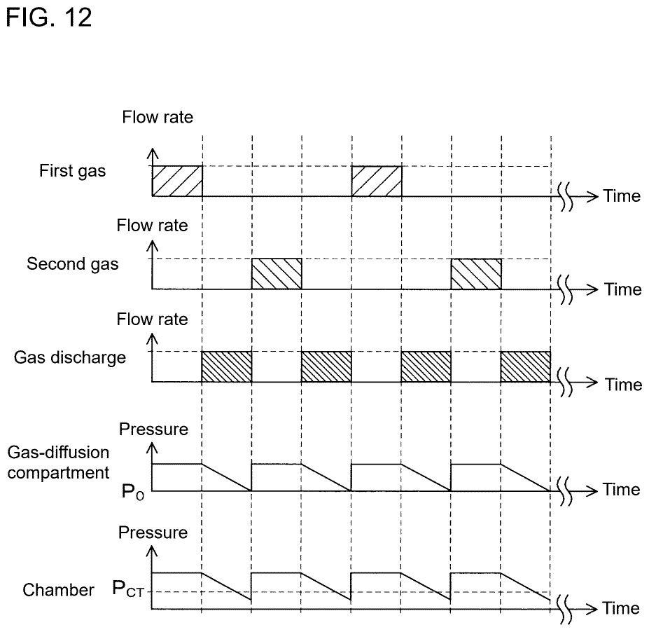

In response to the above, the inventors have conceived an exhaust that performs gas discharge from a gas-diffusion compartment at a sufficiently high rate. The inventors have noticed, however, that such an exhaust has issues described below. As shown in FIG. 12, a method in a comparative example includes supplying a first gas, discharging the first gas with the exhaust, and then supplying a second gas to switch the gases. In this case, the pressure in the gas-diffusion compartment decreases during gas discharge from the gas-diffusion compartment with the exhaust, lowering the pressure in the chamber. The pressure in the chamber can affect plasma generation when decreasing below a pressure threshold P_{CT} for maintaining plasma generation, possibly extinguishing the plasma.

The technique according to one or more aspects of the disclosure thus allows switching gases appropriately during plasma etching. More specifically, the technique includes stopping supply of a first gas, supplying a second gas, and performing gas discharge from a gas-diffusion compartment with an exhaust in the gas-diffusion compartment. In this case, the gas supply is controlled to cause the gas-diffusion compartment to have a pressure higher than or equal to a diffusion-compartment pressure threshold for maintaining plasma in a chamber or cause the chamber to have a pressure higher than or equal to a chamber pressure threshold for maintaining the plasma in the chamber.

A substrate processing apparatus according to the present embodiment will now be described with reference to the drawings. Like reference numerals denote structural elements having substantially the same functions herein. Such components will not be described repeatedly.

### Plasma Etching System

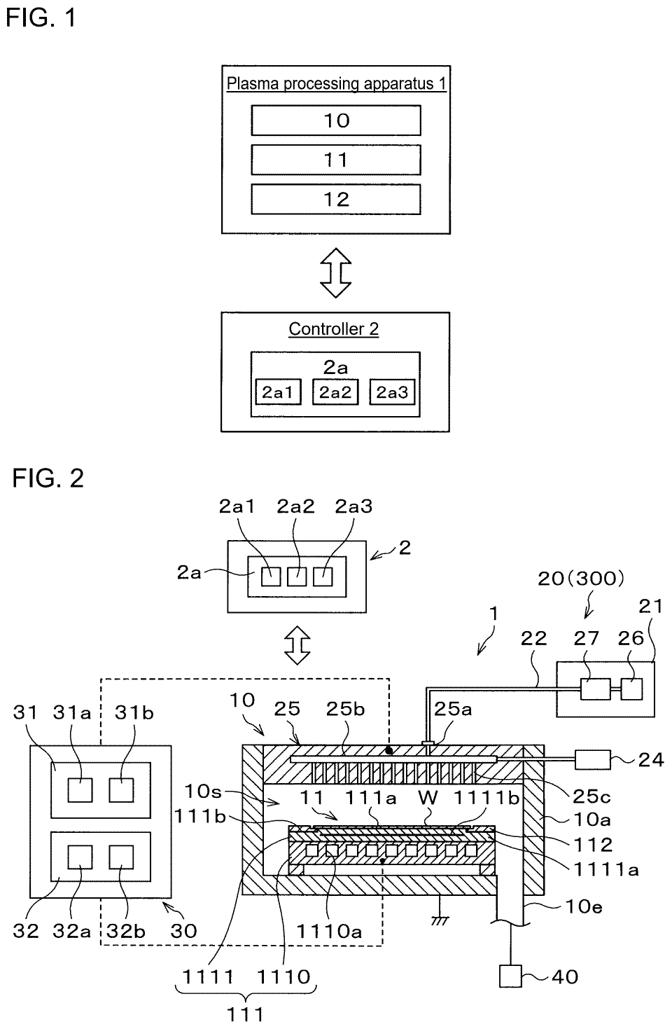

FIG. 1 is a diagram of a plasma etching system, describing an example structure. In one embodiment, the plasma etching system includes a plasma etching apparatus 1 and a controller 2. The plasma etching system is an example of a substrate processing system. The plasma etching apparatus 1 is an example of a substrate processing apparatus. The plasma etching apparatus 1 includes a plasma etching chamber 10 (hereafter referred to as a chamber 10), a substrate support 11, and a plasma generator 12. The chamber 10 has a plasma processing space. The chamber 10 also includes at least one gas inlet for supplying at least one process gas into the plasma processing space and at least one gas outlet for discharging the gas from the plasma processing space. The gas inlet is connected to a gas box 21 (described later). The gas outlet is connected to an exhaust system 40 (described later). The substrate support 11 is located in the plasma processing space and has a substrate support surface for supporting a substrate.

The plasma generator 12 generates plasma PL from at least one process gas supplied into the plasma processing space. The plasma PL generated in the plasma processing space may be capacitively coupled plasma (CCP), inductively coupled plasma (ICP), electron cyclotron resonance plasma (ECR), helicon wave plasma (HWP), or surface wave plasma (SWP). Various plasma generators including an alternating current (AC) plasma generator and a direct current (DC) plasma generator may be used. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions for causing the plasma etching apparatus 1 to perform various steps described in one or more embodiments of the disclosure. The controller 2 may control the components of the plasma etching apparatus 1 to perform various steps described herein. In one embodiment, some or all of the components of the controller 2 may be included in the plasma etching apparatus 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. This program may be prestored in the storage 2a2 or may be obtained through a medium as appropriate. The obtained program is stored into the storage 2a2, loaded from the storage 2a2, and executed by the processor 2a1. The medium may be one of various storage media readable by the computer 2a, or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma etching apparatus 1 through a communication line such as a local area network (LAN).

The functionality of the controller 2 may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry is hardware that carries out or is programmed to perform the recited functionality. The hardware may be any hardware disclosed herein which is programmed or configured to carry out the recited functionality.

### Plasma Etching Apparatus

An example structure of a capacitively coupled plasma etching apparatus 1 as an example of the substrate processing apparatus will now be described. FIG. 2 is a diagram of the capacitively coupled plasma etching apparatus 1, describing an example structure.

The plasma etching apparatus 1 includes a chamber 10, a substrate support 11, a gas supply 20, a power supply 30, and an exhaust system 40.

The substrate support 11 is located in the chamber 10. The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is located on the central area 111a of the body 111. The ring assembly 112 is located on the annular area 111b of the body 111 to surround the substrate W on the central area 111a of the body 111. Thus, the central area 111a is also referred to as a substrate support surface for supporting the substrate W, and the annular area 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central area 111a. In one embodiment, the ceramic member 1111a also includes the annular area 111b. The annular area 111b may be included in a separate member surrounding the ESC 1111, such as an annular ESC or an annular insulating member. In this case, the ring assembly 112 may be placed on either the annular ESC or the annular insulating member or may be placed on both the ESC 1111 and the annular insulating member. At least one RF/DC electrode coupled to an RF power supply 31 or a DC power supply 32, or to both (described later) may be located inside the ceramic member 1111a. In this case, at least one RF/DC electrode serves as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may serve as multiple lower electrodes. The electrostatic electrode 1111b may also function as a lower electrode. Thus, the substrate support 11 includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may also include a temperature control module that adjusts the temperature of at least one of the ESC 1111, the ring assembly 112, or the substrate W to a target temperature. The temperature control module may include a heater, a heat transfer medium, a channel 1110a, or a combination of these. A heat transfer fluid such as brine or gas flows through the channel 1110a. In one embodiment, the channel 1110a is defined in the base 1110, and one or more heaters are located in the ceramic member 1111a in the ESC 1111. The substrate support 11 may include a heat transfer gas supply to supply a heat transfer gas to a space between the back surface of the substrate W and the central area 111a.

As described in detail later, the gas supply 20 includes a gas box 21, a gas channel 22, a gas guide unit, and an exhaust 24. The gas box 21 supplies multiple gases supplied from gas sources each at a controlled flow rate. The gas channel 22 supplies gases supplied from the gas box 21 to the gas guide unit. The gas guide unit introduces two or more process gases into the chamber 10. The exhaust 24 discharges gases introduced into the gas guide unit. The gas guide unit includes a shower head 25. The shower head 25 is located above the substrate support 11. In one embodiment, the shower head 25 defines at least a part of the ceiling of the chamber 10. The chamber 10 has a plasma processing space 10s defined by the shower head 25, a side wall 10a of the chamber 10, and the substrate support 11. The chamber 10 is grounded. The shower head 25 and the substrate support 11 are electrically insulated from the housing of the chamber 10.

The shower head 25 introduces the process gases from the gas box 21 into the plasma processing space 10s. The shower head 25 includes at least one gas inlet 25a, at least one gas-diffusion compartment 25b, and multiple gas guides 25c. The process gases supplied to the gas inlet 25a flows through the gas-diffusion compartment 25b and is introduced into the plasma processing space 10s through the gas guides 25c. The shower head 25 also includes at least one upper electrode. In addition to the shower head 25, the gas guide unit may include one or more side gas injectors (SGIs) installed in one or more openings in the side wall 10a.

The gas box 21 may include at least one gas source 26 and at least one flow controller 27. In one embodiment, the gas box 21 supplies two or more process gases from the corresponding gas sources 26 to the shower head 25 through the corresponding flow controllers 27. Each flow controller 27 may include, for example, a mass flow controller or a pressure-based flow controller. The gas box 21 may further include at least one flow rate modulator that allows supply of at least one process gas at a modulated flow rate or in a pulsed manner.

The power supply 30 includes the RF power supply 31 coupled to the chamber 10 through at least one impedance matching circuit. The RF power supply 31 provides at least one RF signal (RF power) to at least one lower electrode or at least one upper electrode, or to both. This causes the plasma PL to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the generated plasma to the substrate W.

In one embodiment, the RF power supply 31 includes a first RF generator 31a and a second RF generator 31b. The first RF generator 31a is coupled to at least one lower electrode or at least one upper electrode, or to both through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated one or more source RF signals are provided to at least one lower electrode or at least one upper electrode, or to both.

The second RF generator 31b is coupled to at least one lower electrode through at least one impedance matching circuit and generates a bias RF signal (bias RF power). The bias RF signal may have a frequency that is the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may include the DC power supply 32 coupled to the chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode or at least one upper electrode, or to both. The voltage pulse may have a rectangular, trapezoidal, triangular pulse waveform, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive or negative polarity. The sequence of voltage pulses may also include one or more positive voltage pulses and one or more negative voltage pulses within one cycle. The power supply 30 may include the first DC generator 32a and the second DC generator 32b in addition to the RF power supply 31, or the first DC generator 32a may replace the second RF generator 31b.

The exhaust system 40 is connectable to, for example, a gas outlet 10e in the bottom of the chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

### First Embodiment

### Gas Supply

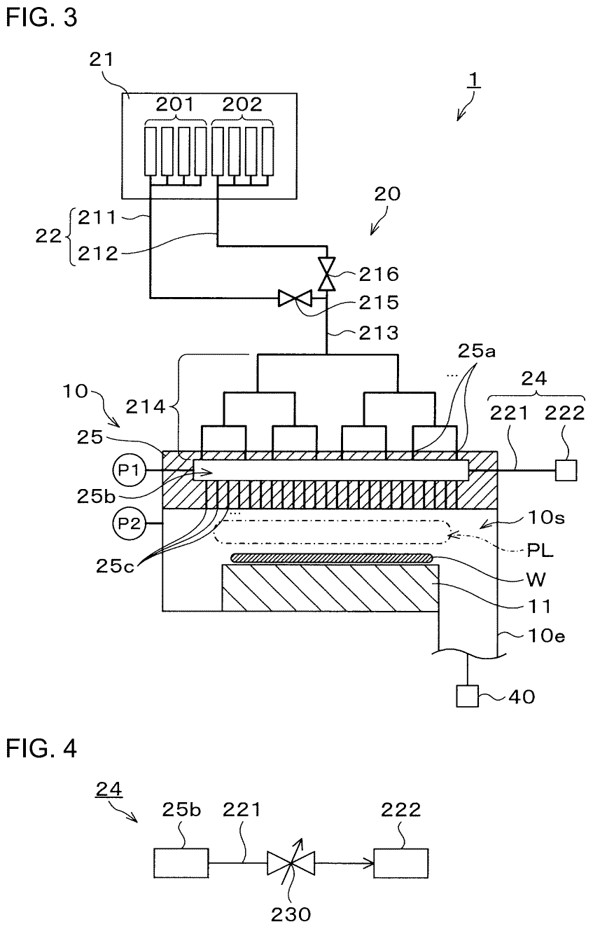

The gas supply 20 in a first embodiment will now be described with reference to FIGS. 3 to 5. FIG. 3 is a schematic diagram of the gas supply 20, showing an example structure. In FIG. 3, the chamber 10, a part of the substrate support 11, and the plasma generator 12 in the plasma etching apparatus 1 are not shown for ease of explanation.

The gas box 21 in FIG. 3 includes a first gas source 201 that supplies a first gas and a second gas source 202 that supplies a second gas. The first gas source 201 and the second gas source 202 may each include multiple gas sources. The first gas source 201 and the second gas source 202 may share some gas sources. The first gas and the second gas may be known gases that can selectively etch either a silicon nitride film or a silicon oxide film.

The gas channel 22 includes a first channel 211 through which the first gas flows downstream from the first gas source 201. The gas channel 22 includes a second channel 212 through which the second gas flows downstream from the second gas source 202. The gas channel 22 also includes a common channel 213 downstream from the first channel 211 and the second channel 212, which merge into the common channel 213 to allow either gas to flow. The common channel 213 in the present embodiment includes a branched portion 214 that distributes the gas with a uniform pressure in a plane direction. The common channel 213 has downstream ends in the branched portion 214 connected to multiple gas inlets 25a in the shower head 25. The first channel 211 includes a first valve 215 at its end connected to the common channel 213. The second channel 212 includes a second valve 216 at its end connected to the common channel 213.

The gas channel 22 with this structure allows, for example, the first gas supplied from the first gas source 201 to flow through the first channel 211 into the common channel 213 with the first valve 215 being open and the second valve 216 being closed. The first gas is distributed through the branched portion 214 in the common channel 213 to the downstream ends in the branched portion 214 and then flows into the gas-diffusion compartment 25b through the gas inlets 25a in the shower head 25. The first gas diffuses in the gas-diffusion compartment 25b to have a substantially uniform pressure distribution in the plane direction, and is then introduced into the chamber 10 through the gas guides 25c.

The gas-diffusion compartment 25b includes a pressure gauge P1. The pressure gauge P1 measures the pressure inside the gas-diffusion compartment 25b and transmits, for example, measurement information to the controller 2.

The chamber 10 includes a pressure gauge P2. The pressure gauge P2 measures the pressure inside the chamber 10 and transmits, for example, measurement information to the controller 2.

The gas-diffusion compartment 25b is connected to the exhaust 24. The exhaust 24 includes an exhaust channel 221 and a vacuum pump 222. The exhaust channel 221 has one end connected to the gas-diffusion compartment 25b and the other end connected to the vacuum pump 222 to allow a gas to flow through the exhaust channel 221. The vacuum pump 222 may include a turbomolecular pump, a dry pump, or a combination of these. The vacuum pump 222 may be included in the exhaust system 40.

In one embodiment, multiple exhaust channels 221 are arranged to have their ends connected to the gas-diffusion compartment 25b in a manner circumferentially equally spaced in a plan view of the gas-diffusion compartment 25b. This allows gas discharge from the gas-diffusion compartment 25b with a uniform pressure distribution in the plane direction.

In one embodiment, as shown in FIG. 4, the exhaust 24 includes a control valve 230 in the exhaust channel 221. The control valve 230 may have the degree of opening, the opening and closing timing, or an opening duration controlled by, for example, the controller 2 to adjust the flow rate of the gas flowing through the exhaust channel 221.

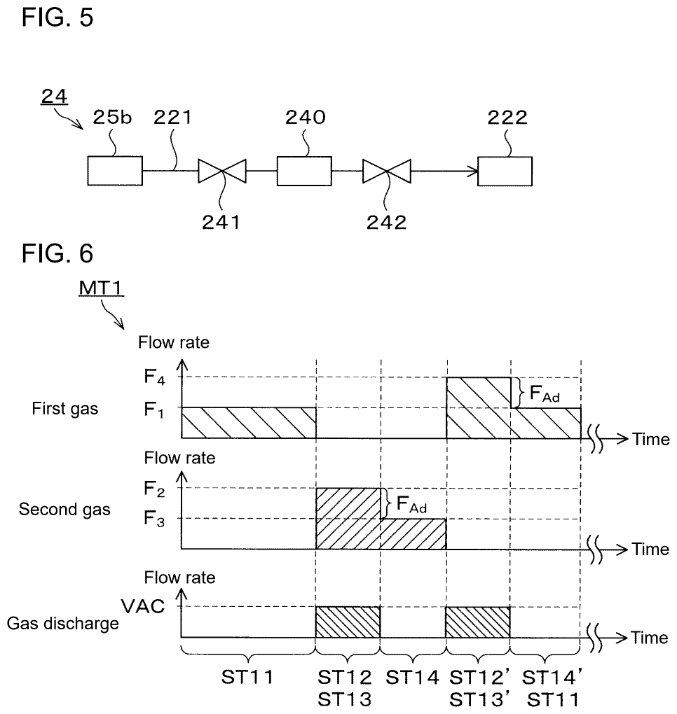

In another embodiment, as shown in FIG. 5, the exhaust 24 includes a tank 240 in the exhaust channel 221, a first tank valve 241 upstream from the tank 20, and a second tank valve 242 downstream from the tank 240. The tank 240 has an internal space maintainable at a negative pressure with respect to the gas-diffusion compartment 25b. In one embodiment, the tank 240 has substantially the same volume as the gas-diffusion compartment 25b.

### Gas Supply Method

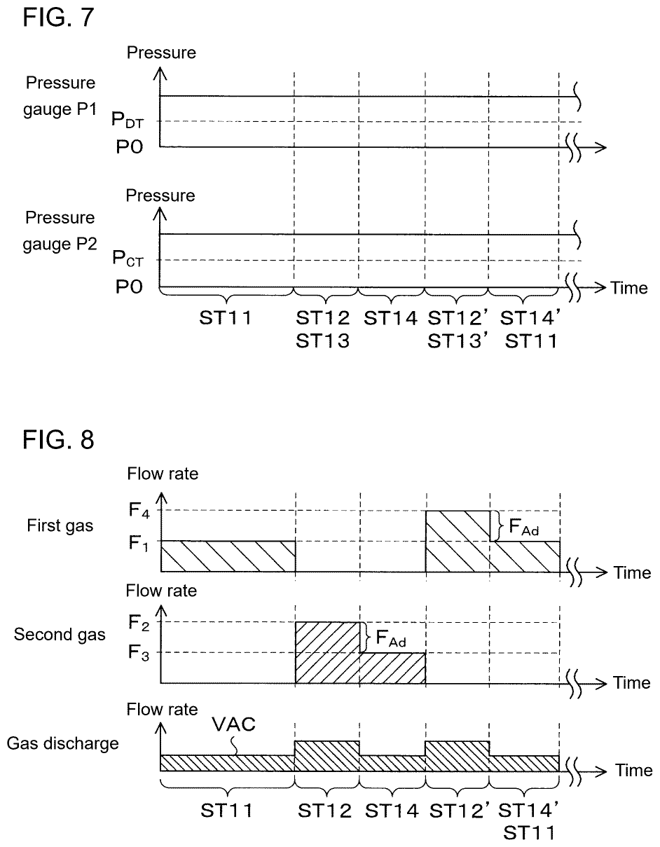

A gas supply method MT1 for supplying a gas into the chamber 10 implementable with the gas supply 20 in the first embodiment will now be described with reference to FIGS. 6 and 7. FIG. 6 is a sequence chart of control over, with the gas supply method MT1, the flow rate of the first gas supplied from the first gas source 201 or the second gas supplied from the second gas source 202 and over an exhaust flow rate at which gas discharge from the gas-diffusion compartment 25b is performed by the exhaust 24.

The gas supply method MT1 includes switching the gas supplied into the chamber 10 from the first gas to the second gas or from the second gas to the first gas. The gas supply method MT1 includes steps ST11 to ST14 described below.

In step ST11, the first gas source 201 starts supplying the first gas at a first flow rate F₁ to generate the plasma PL and stops supplying the first gas after an intended duration. In one embodiment, the first flow rate F₁ is a flow rate for maintaining the chamber 10 at an intended pressure to maintain the plasma PL generated from the first gas in the chamber 10. In this state, the gas-diffusion compartment 25b is maintained at a pressure higher than or equal to a diffusion-compartment pressure threshold P_{DT}. The diffusion-compartment pressure threshold P_{DT} is a value predetermined as a pressure in the gas-diffusion compartment 25b to allow the plasma PL to be maintained in the chamber 10. The diffusion-compartment pressure threshold P_{DT} is predetermined based on the plasma processing conditions such as gas species, the frequency or the voltage of the RF signal, the temperature in the chamber 10, or the volume of the chamber 10. When the pressure in the gas-diffusion compartment 25b is higher than or equal to the diffusion-compartment pressure threshold P_{DT}, the chamber 10 is maintained at an intended pressure, and the plasma is maintained in the chamber 10. The diffusion-compartment pressure threshold P_{DT} may be determined experimentally or by simulation for each plasma processing condition.

In step ST12, the second gas source 202 starts supplying the second gas at a second flow rate F₂. The second flow rate F₂ will be described later.

In step ST13, the exhaust 24 performs gas discharge from the gas-diffusion compartment 25b at an exhaust flow rate VAC (described later). During gas discharge, the gas-diffusion compartment 25b is maintained at an intended pressure as shown in FIG. 7 for the reasons described later. After an exhaust duration (described later), the gas discharge from the gas-diffusion compartment 25b is stopped.

In step ST14, the flow rate of the second gas supplied from the second gas source 202 is changed from the second flow rate F₂ to a third flow rate F₃. The second gas is continuously supplied for an intended duration. In one embodiment, the third flow rate F₃ is lower than the second flow rate F₂. The third flow rate F₃ is a flow rate for maintaining the chamber 10 at an intended pressure to maintain the plasma PL generated from the second gas in the chamber 10.

The switching from the first gas to the second gas is complete after steps ST11 to ST14 above. In step ST11 and step ST14, plasma etching of the substrate W placed in the chamber 10 can be performed with the plasma PL generated from the first gas or the plasma PL generated from the second gas.

After step ST14, the second gas supply is stopped. The first gas is then supplied at a fourth flow rate F₄ in step ST12′ similar to step ST12, and the second gas is then discharged in step ST13′ similar to step ST13. This switches the second gas to the first gas. After switching to the first gas, the flow rate of the first gas is changed from the fourth flow rate F₄ to the first flow rate F₁ in step ST14′ similar to step ST14. The processing then returns to step ST11. When switching to the first gas, the first flow rate F₁ of the first gas corresponds to the third flow rate F₃ of the second gas, and the fourth flow rate F₄ of the first gas corresponds to the second flow rate F₂ of the second gas. The plasma etching can then be continued until the first gas and the second gas are switched an intended number of times.

The second flow rate F₂ in step ST12 will now be described. The first gas supplied in step ST11 remains in the common channel 213 and the gas-diffusion compartment 25b when the supply of the first gas ends. When the supply of the second gas starts in step ST12, the second gas sequentially fills the common channel 213 and the gas-diffusion compartment 25b. The second gas expels the first gas remaining in the common channel 213 toward the gas-diffusion compartment 25b. The first gas expelled in this manner is sequentially discharged in step ST13.

In a comparative example, the second gas is supplied in step ST12 at a flow rate substantially equal to the exhaust flow rate VAC when the first gas is sequentially discharged in step ST13. In this comparative example, the first gas is expelled through the common channel 213 at a flow rate substantially the same as the exhaust flow rate VAC. In step ST13, the exhaust 24 performs gas discharge. The gas is thus apparently supplied into the gas-diffusion compartment 25b at a flow rate obtained by subtracting the exhaust flow rate VAC from the flow rate of the first gas expelled through the common channel 213. Such an apparent flow rate is insufficient to maintain the gas-diffusion compartment 25b at a pressure higher than or equal to the diffusion-compartment pressure threshold P_{DT}. Thus, the flow rate of the gas introduced into the chamber 10 from the gas-diffusion compartment 25b decreases during step ST13. This can lower the pressure in the chamber 10 below the chamber pressure threshold P_{CT} for maintaining the generation of the plasma PL, possibly extinguishing the plasma PL (refer to FIG. 12). The chamber pressure threshold P_{CT} is a value predetermined based on the plasma processing conditions such as gas species, the frequency or the voltage of the RF signal, the temperature in the chamber 10, or the volume of the chamber 10. When the chamber 10 is at a pressure equal to or higher than the chamber pressure threshold P_{CT}, the plasma is maintained in the chamber 10. The chamber pressure threshold P_{CT} may be determined experimentally or by simulation for each plasma processing condition. In one embodiment, the chamber pressure threshold P_{CT} is higher than or equal to 5 mTorr.

In contrast, the gas supply method MT1 in the present embodiment supplies the second gas at the second flow rate F₂ in step ST12. The first gas is thus expelled through the common channel 213 at a flow rate substantially the same as the second flow rate F₂. The second flow rate F₂ is obtained by adding a presupply flow rate F_{Ad} to the third flow rate F₃ and is thus higher than the third flow rate F₃. The presupply of the second gas herein refers to the second gas being preliminarily supplied (step ST12) during discharging of the first gas in step ST13 before step ST14 in which the second gas is used for plasma processing of the substrate W. As shown in FIG. 6, the presupply flow rate F_{Ad} is a flow rate added to the third flow rate for a period overlapping the exhaust duration in step ST13. In one embodiment, the second flow rate F₂ is the sum of the third flow rate F₃ and the exhaust flow rate VAC. In step ST13, the exhaust 24 performs gas discharge. The gas is thus apparently supplied into the gas-diffusion compartment 25b at a flow rate obtained by subtracting the exhaust flow rate VAC from the second flow rate F₂. The second gas is supplied into the gas-diffusion compartment 25b at such an apparent flow rate, maintaining the gas-diffusion compartment 25b at a pressure higher than the diffusion-compartment pressure threshold P_{DT} during step ST13 as shown in FIG. 7.

The exhaust flow rate VAC in step ST13 will now be described. The exhaust flow rate VAC allows the apparent flow rate, which is obtained by subtracting the exhaust flow rate VAC from the second flow rate F₂, to be sufficient to maintain the gas-diffusion compartment 25b at an intended pressure during step ST13. In one example, the exhaust flow rate VAC may be substantially the same as the presupply flow rate F_{Ad} included in the second flow rate F₂. In this case, the apparent flow rate obtained by subtracting the exhaust flow rate VAC from the second flow rate F₂ is substantially the same as the third flow rate F₃. The apparent flow rate is sufficient to maintain the gas-diffusion compartment 25b at a pressure higher than or equal to the diffusion-compartment pressure threshold P_{DT}.

The exhaust duration in step ST13 will now be described. The exhaust duration is, but not limited to, a duration for which the first gas filling the gas-diffusion compartment 25b and the common channel 213 is discharged sufficiently. The exhaust duration can be determined based on, for example, the sum of the volumes of the gas-diffusion compartment 25b and the common channel 213, the gas temperature, the exhaust flow rate VAC, and the flow rate of the gas introduced into the chamber 10 from the gas-diffusion compartment 25b.

An example gas discharge method performed by the exhaust 24 in step ST13 will now be described. In the example structure including the control valve 230 shown in FIG. 4, the opening and closing, the degrees of opening and closing, and the opening duration of the control valve 230 are controlled to regulate the start and the end of gas discharge and the exhaust flow rate VAC. To regulate the exhaust flow rate VAC with the control valve 230, the presupply flow rate F_{Ad} included in the second flow rate F₂ may also be regulated together with the exhaust flow rate VAC to allow the presupply flow rate F_{Ad} to be substantially the same as the exhaust flow rate VAC. In some embodiments, the pressure value measured by the pressure gauge P1 included in the gas-diffusion compartment 25b may be referenced to control the exhaust flow rate VAC with the control valve 230 to maintain the pressure value at an intended value.

In the example structure including the tank 240 shown in FIG. 5, the first tank valve 241 is open to start gas discharge in step ST13. The tank 240 is preliminarily maintained at a negative pressure with respect to the gas-diffusion compartment 25b. This allows connection between the gas-diffusion compartment 25b and the tank 240 in response to the first tank valve being open, discharging the gas in the gas-diffusion compartment 25b into the tank 240. In the example structure with the tank 240 having substantially the same volume as the gas-diffusion compartment 25b in one embodiment, the tank 240 may be maintained to be a vacuum. In this case, all the gas remaining in the gas-diffusion compartment 25b is promptly discharged into the tank 240 in response to the first tank valve 241 being open in step ST13. This allows prompt discharge of the remaining gas, achieving prompt gas switching.

A modification of the gas supply method MT1 implementable with the gas supply 20 in the first embodiment will now be described with reference to FIG. 8. FIG. 8 is a sequence chart of control over, with the gas supply method MT1, the flow rate of the first gas supplied from the first gas source or the second gas supplied from the second gas source and over the exhaust flow rate VAC at which gas discharge from the gas-diffusion compartment 25b is performed.

In the modification shown in FIG. 8, the exhaust 24 constantly performs gas discharge from the gas-diffusion compartment 25b during an operation with the gas supply method MT1, instead of performing the processing in step ST13. In this modification, the pressure value measured by the pressure gauge P1 included in the gas-diffusion compartment 25b is referenced to control the exhaust flow rate VAC with the control valve 230 to maintain the pressure value at an intended value. Such control may be known feedback control based on the pressure value. This can maintain the gas-diffusion compartment 25b at an intended pressure.

### Second Embodiment

### Gas Supply

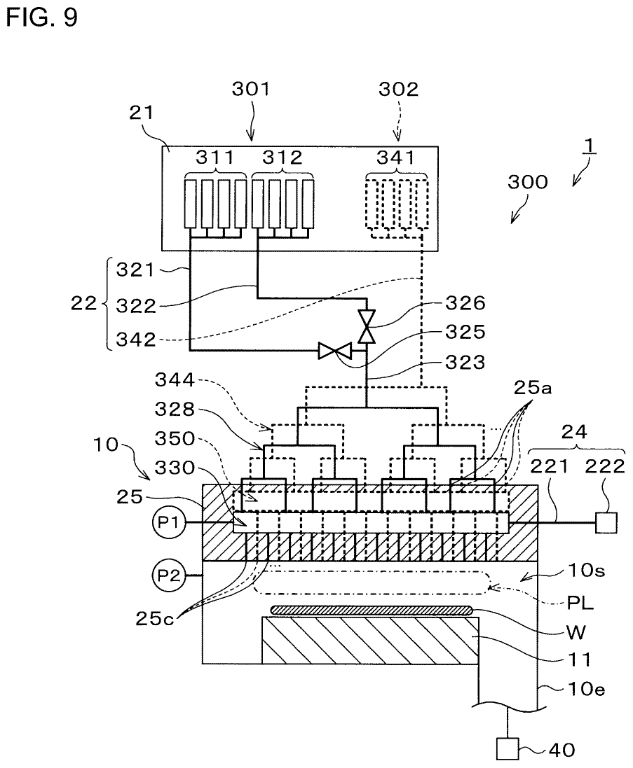

A gas supply 300 according to a second embodiment will now be described with reference to FIGS. 9 to 11. FIG. 9 is a schematic diagram of the gas supply 300. In FIG. 9, the gas supply 300 includes a first gas line 301 and a second gas line 302. For clarity, the components of the first gas line 301 are illustrated with solid lines, and the components of the second gas line 302 are illustrated with dotted lines.

The first gas line 301 has the same structure as the gas supply 20 in the first embodiment. More specifically, the gas box 21 includes, in the first gas line 301, a first gas source 311 that supplies a first gas and a second gas source 312 that supplies a second gas. The gas channel 22 includes a first channel 321 through which the first gas flows downstream from the first gas source 311. The gas channel 22 includes a second channel 322 through which the second gas flows downstream from the second gas source 312. The gas channel 22 also includes a common channel 323 downstream from the first channel 321 and the second channel 322, which merge into the common channel 323 to allow either gas to flow. The first channel 321 includes a first valve 325 at its end connected to the common channel 323. The second channel 322 includes a second valve 326 at its end connected to the common channel 323. The common channel 323 in the present embodiment includes a branched portion 328 that distributes the gas with a uniform pressure in a plane direction. The common channel 323 has downstream ends in the branched portion 328 connected to multiple gas inlets 25a in a first gas-diffusion compartment 330 in the shower head 25.

The first gas line 301 with this structure allows, for example, the first gas supplied from the first gas source 311 to flow through the first channel 321 into the common channel 323 with the first valve 325 being open and the second valve 326 being closed. The first gas is distributed through the branched portion 328 in the common channel 323 to the downstream ends in the branched portion 328 and then flows into the first gas-diffusion compartment 330 through the gas inlets 25a in the shower head 25. The first gas diffuses to have a substantially uniform pressure distribution in the plane direction in the first gas-diffusion compartment 330, and is then introduced into the chamber 10 through gas guides 25c in the first gas-diffusion compartment 330.

The first gas-diffusion compartment 330 includes a pressure gauge P1. The pressure gauge P1 measures the pressure inside the first gas-diffusion compartment 330 and transmits, for example, measurement value information to the controller 2. The first gas-diffusion compartment 330 is connected to the exhaust 24. The exhaust 24 has the same structure and is controlled with the same method as in the first embodiment.

The second gas line 302 includes a third gas source 341 that supplies a third gas and a third channel 342. The third gas source 341 may include multiple gas sources. The first gas source 311 and the second gas source 312 may share some gas sources. The third channel 342 includes a branched portion 344. The third channel 342 has downstream ends in the branched portion 344 connected to multiple gas inlets 25a in a second gas-diffusion compartment 350 in the shower head 25. The third gas may contain, for example, the same carrier gas as the first gas or the second gas. The carrier gas may contain, for example, an Ar gas or an O₂ gas, or both.

The second gas line 302 with this structure allows, for example, the third gas supplied from the third gas source 341 to be distributed through the branched portion 344 in the third channel 342 to the downstream ends in the branched portion 344. The third gas then flows into the second gas-diffusion compartment 350 through the gas inlets 25a in the shower head 25. The third gas diffuses to have a substantially uniform pressure distribution in the plane direction in the second gas-diffusion compartment 350, and is then introduced into the chamber 10 through gas guides 25c in the second gas-diffusion compartment 350.

The first gas-diffusion compartment 330 and the second gas-diffusion compartment 350 in the shower head 25 are independent of each other to allow each gas to flow separately. More specifically, the second gas line can supply a gas into the chamber 10 without the gas flowing through at least the first gas-diffusion compartment 330. The exhaust 24 is connected to the first gas-diffusion compartment 330 alone. The exhaust 24 thus performs gas discharge from the first gas-diffusion compartment 330 alone, and does not perform gas discharge from the second gas-diffusion compartment 350.

### Gas Supply Method

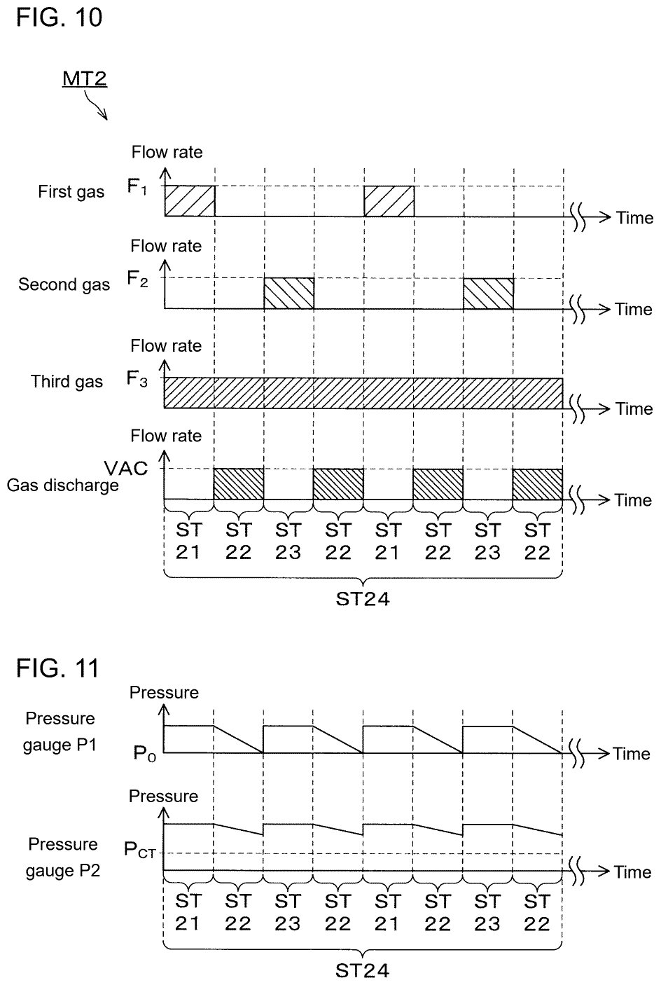

A gas supply method MT2 for supplying a gas into the chamber 10 implementable with the gas supply 300 in the second embodiment will now be described with reference to FIG. 10. FIG. 10 is a sequence chart of control over, with the gas supply method MT2, the flow rate of the first gas or the second gas supplied from the first gas line 301, or the third gas supplied from the second gas line 302 and over the exhaust flow rate at which gas discharge from the first gas-diffusion compartment 330 is performed.

The gas supply method MT2 allows switching the gas supplied into the chamber 10 from the first gas to the second gas or from the second gas to the first gas as appropriate. The gas supply method MT2 includes steps ST21 to ST24 described below.

In step ST21, the first gas source 311 starts supplying the first gas at the first flow rate F₁ to generate plasma PL and stops supplying the first gas after an intended duration. In one embodiment, the first flow rate F₁ is used to maintain the chamber 10 at an intended pressure to maintain the plasma PL generated from the first gas in the chamber 10.

In step ST22, the exhaust 24 performs gas discharge from the first gas-diffusion compartment 330 at the exhaust flow rate VAC (described later). During gas discharge, the chamber 10 is maintained at a pressure higher than or equal to the chamber pressure threshold P_{CT} for the reasons described later. After the exhaust duration (described later), the gas discharge from the first gas-diffusion compartment 330 is stopped.

In step ST23, the second gas source 312 starts supplying the second gas at the second flow rate F₂. In one embodiment, the second flow rate F₂ is a flow rate for maintaining the chamber 10 at an intended pressure to maintain the plasma PL generated from the second gas in the chamber 10.

In step ST24, the third gas is continuously supplied from the third gas source 341 at the third flow rate F₃ through the second gas line 302 during steps ST21 to ST23. The third flow rate F₃ will be described later.

The switching from the first gas to the second gas is complete after steps ST21 to ST24 above. In step ST21 and step ST23, plasma etching of the substrate placed in the chamber 10 can be performed with the plasma PL generated from the first gas or the plasma PL generated from the second gas. After step ST23, the second gas supply is stopped. The processing in step ST22 and step ST21 is performed in this order while the processing in step ST24 is being performed continuously. This switches the second gas to the first gas. The plasma etching can then be continued until the first gas and the second gas are being switched an intended number of times.

The processing in step ST24 will now be described in detail. The first gas supplied in step ST21 is discharged sequentially from the common channel 323 and the first gas-diffusion compartment 330 in step ST22 after the first gas supply ends. During step ST22, no gas is supplied into the first gas-diffusion compartment 330. Thus, the pressure value measured by the pressure gauge P1 included in the first gas-diffusion compartment 330 approaches a vacuum value P₀ as shown in the upper part of FIG. 11.

In a comparative example, the third gas is not supplied through the second gas line 302 in step ST24. In this case, the pressure in the chamber 10 can decrease, until the second gas is supplied in step ST23, below the chamber pressure threshold P_{CT} for maintaining the generation of the plasma PL, possibly extinguishing the plasma PL (refer to FIG. 12). The chamber pressure threshold P_{CT} is defined as in the first embodiment described above.

In contrast, the gas supply method MT2 in the present embodiment supplies the third gas into the chamber 10 at the third flow rate F₃ in step ST24. As shown in the lower part of FIG. 11, the pressure value measured by the pressure gauge P2 included in the chamber 10 is sufficiently higher than the chamber pressure threshold P_{CT} for maintaining the plasma PL, maintaining the chamber 10 at a sufficiently high pressure.

The third flow rate F₃ is used to maintain the chamber 10 at an intended pressure to maintain the plasma PL generated from a gas containing the first gas supplied from the first gas line 301 and the third gas supplied from the second gas line 302 in the chamber 10. In the first gas line 301, the first gas introduced into the chamber 10 has a pressure decreasing in step ST22. The third flow rate F₃ is thus sufficient to generate a pressure in the chamber 10 that compensates for the decreased pressure. In one embodiment, the third flow rate F₃ is substantially the same as the exhaust flow rate VAC during the gas discharge in step ST22. In this case, the third gas is supplied at the third flow rate F₃, which is the same as the flow rate of the first gas discharged from the first gas-diffusion compartment 330 at the exhaust flow rate VAC in step ST22. The chamber 10 is thus maintained at a pressure higher than or equal to the chamber pressure threshold P_{CT}.

Additionally, the first gas-diffusion compartment 330 can be filled with a gas through the first gas line 301 at a lower pressure than in the first embodiment. This shortens the time taken for performing gas discharge from the first gas-diffusion compartment 330 as a secondary effect. Filling the first gas-diffusion compartment 330 with a gas at a lower pressure can reduce the likelihood of abnormal electric discharge.

The embodiments described herein are illustrative in all aspects and should not be construed to be restrictive. The components in the above embodiments may be eliminated, substituted, or modified in various forms without departing from the spirit and scope of the appended claims. For example, the components in the above embodiments may be combined as appropriate. These combinations produce the same advantageous effects as the respective embodiments in the combinations, as well as other advantageous effects that are apparent to those skilled in the art from the embodiments described herein.

The effects described herein are merely illustrative or exemplary and are not limitative. In other words, the technique according to one or more embodiments of the disclosure may produce other effects that will be apparent to those skilled in the art from the embodiments described herein, in addition to or in place of the above effects.

The example structures described below may also fall within the technical scope of the disclosure.
(1) A plasma etching apparatus, comprising:
a chamber;
a gas supply configured to supply a gas into the chamber; and
a controller,
wherein the gas supply includes
   a gas box configured to supply the gas,
   a gas-diffusion compartment configured to diffuse the gas from the gas box inside the gas-diffusion compartment and introduce the gas into the chamber, and
   an exhaust configured to discharge the gas in the gas-diffusion compartment,
   the controller controls operations including
   (a) supplying a first gas from the gas box at a first flow rate to generate plasma in the chamber, and
   (b) stopping supply of the first gas from the gas box, supplying a second gas from the gas box at a second flow rate, and performing gas discharge from the gas-diffusion compartment, and
(b) includes maintaining the gas-diffusion compartment at a pressure higher than or equal to a threshold predetermined based on a plasma processing condition as a pressure at which the plasma is maintained in the chamber.
(2) The plasma etching apparatus according to (1), wherein
the controller further controls operations including
   (c) stopping the gas discharge from the gas-diffusion compartment after (b), and
   (d) continuously supplying the second gas from the gas box at a third flow rate lower than the second flow rate, and
(c) and (d) include maintaining the gas-diffusion compartment at a pressure higher than or equal to the threshold.
(3) The plasma etching apparatus according to (2), wherein the second flow rate is a sum of the third flow rate and an exhaust flow rate at which the gas discharge from the gas-diffusion compartment is performed in (b).
(4) A plasma etching apparatus, comprising:
a chamber;
a gas supply configured to supply a gas into the chamber; and
a controller,
wherein the gas supply includes
   a gas box configured to supply the gas,
   a first gas line including
      a gas-diffusion compartment configured to diffuse the gas from the gas box and introduce the gas into the chamber, and
      an exhaust configured to discharge the gas in the gas-diffusion compartment, and
   a second gas line configured to supply the gas into the chamber without the gas flowing through at least the gas-diffusion compartment in the first gas line,
the controller controls operations including
   (a) supplying a first gas from the gas box at a first flow rate through the first gas line to generate plasma in the chamber,
   (b) stopping supply of the first gas from the gas box through the first gas line, performing gas discharge from the gas-diffusion compartment, and supplying a second gas from the gas box through the first gas line at a second flow rate, and
   (c) during at least (b), supplying a third gas from the gas box at a third flow rate through the second gas line, and
(b) and (c) include maintaining the gas-diffusion compartment at a pressure higher than or equal to a threshold predetermined based on a plasma processing condition as a pressure at which the plasma is maintained in the chamber.
(5) The plasma etching apparatus according to (4), wherein performing the gas discharge from the gas-diffusion compartment through the first gas line in (b) is performed at an exhaust flow rate being same as the third flow rate.
(6) The plasma etching apparatus according to any one of (1) to (5), wherein
the exhaust includes a tank having an internal space maintainable at a negative pressure with respect to the gas-diffusion compartment, and
the controller connects the gas-diffusion compartment to the tank to perform the gas discharge from the gas-diffusion compartment.
(7) The plasma etching apparatus according to (6), wherein the tank has a same volume as the gas-diffusion compartment.
(8) A plasma etching method implementable with a plasma etching apparatus, the plasma etching apparatus including
a chamber, and
a gas supply configured to supply a gas into the chamber, the gas supply including
   a gas box configured to supply the gas,
   a gas-diffusion compartment configured to diffuse the gas from the gas box inside the gas-diffusion compartment and introduce the gas into the chamber, and
   an exhaust configured to discharge the gas in the gas-diffusion compartment,
the plasma etching method comprising:
(a) supplying a first gas from the gas box at a first flow rate to generate plasma in the chamber; and
(b) stopping supply of the first gas from the gas box, supplying a second gas from the gas box at a second flow rate, and performing gas discharge from the gas-diffusion compartment,
wherein (b) includes maintaining the gas-diffusion compartment at a pressure higher than or equal to a threshold predetermined based on a plasma processing condition as a pressure at which the plasma is maintained in the chamber.
(9) The plasma etching method according to (8), further comprising:
(c) stopping the gas discharge from the gas-diffusion compartment after (b); and
(d) continuously supplying the second gas from the gas box at a third flow rate lower than the second flow rate,
wherein (c) and (d) include maintaining the gas-diffusion compartment at a pressure higher than or equal to the threshold.
(10) The plasma etching method according to (9), wherein
the second flow rate is a sum of the third flow rate and an exhaust flow rate at which the gas discharge from the gas-diffusion compartment is performed in (b).

### REFERENCE SIGNS LIST

F₁ First flow rate F₁
F₂ Second flow rate F₂
VAC Exhaust flow rate VAC
1 Plasma etching apparatus
2 Controller
10 Chamber
20 Gas supply
21 Gas box
24 Exhaust
25b Gas-diffusion compartment

1. A plasma etching apparatus, comprising:
a chamber;
a gas supply configured to supply a gas into the chamber; and
circuitry, wherein
the gas supply includes:
a gas box configured to supply the gas,
a gas-diffusion compartment configured to diffuse the gas from the gas box inside the gas-diffusion compartment and introduce the gas into the chamber, and
an exhaust configured to discharge the gas in the gas-diffusion compartment,
the circuitry is configured to control operations including:
(a) supplying a first gas from the gas box at a first flow rate to generate plasma in the chamber, and
(b) stopping supply of the first gas from the gas box, supplying a second gas from the gas box at a second flow rate, and performing gas discharge from the gas-diffusion compartment, and
(b) includes setting the gas-diffusion compartment at a pressure at which the plasma is maintained in the chamber.

2. The plasma etching apparatus according to claim 1, wherein
the circuitry is further configured to control operations including:
(c) stopping the gas discharge from the gas-diffusion compartment after (b), and
(d) continuously supplying the second gas from the gas box at a third flow rate lower than the second flow rate, and
(c) and (d) include setting the gas-diffusion compartment at a pressure at which the plasma is maintained in the chamber.

3. The plasma etching apparatus according to claim 2, wherein the second flow rate is a sum of the third flow rate and an exhaust flow rate at which the gas discharge from the gas-diffusion compartment is performed in (b).

4. A plasma etching apparatus, comprising:
a chamber;
a gas supply configured to supply a gas into the chamber; and
circuitry, wherein
the gas supply includes:
a gas box configured to supply the gas,
a first gas line including:
a gas-diffusion compartment configured to diffuse the gas from the gas box and introduce the gas into the chamber, and
an exhaust configured to discharge the gas in the gas-diffusion compartment, and
a second gas line configured to supply the gas into the chamber without the gas flowing through at least the gas-diffusion compartment in the first gas line,
the circuitry is configured to control operations including:
(a) supplying a first gas from the gas box at a first flow rate to generate plasma in the chamber,
(b) stopping supply of the first gas from the gas box through the first gas line, performing gas discharge from the gas-diffusion compartment, and supplying a second gas from the gas box through the first gas line at a second flow rate, and
(c), during at least (b), supplying a third gas from the gas box at a third flow rate through the second gas line, and
(b) and (c) include setting the chamber at a pressure at which the plasma is maintained in the chamber.

5. The plasma etching apparatus according to claim 4, wherein performing the gas discharge from the gas-diffusion compartment through the first gas line in (b) is performed at an exhaust flow rate being same as the third flow rate.

6. The plasma etching apparatus according to claim 1, wherein
the exhaust includes a tank having an internal space maintainable at a negative pressure with respect to the gas-diffusion compartment, and
the circuitry is configured to connect the gas-diffusion compartment to the tank to perform the gas discharge from the gas-diffusion compartment.

7. The plasma etching apparatus according to claim 6, wherein the tank has a same volume as the gas-diffusion compartment.

8. The plasma etching apparatus according to claim 2, wherein
the exhaust includes a tank having an internal space maintainable at a negative pressure with respect to the gas-diffusion compartment, and
the circuitry is configured to connect the gas-diffusion compartment to the tank to perform the gas discharge from the gas-diffusion compartment.

9. The plasma etching apparatus according to claim 8, wherein the tank has a same volume as the gas-diffusion compartment.

10. The plasma etching apparatus according to claim 3, wherein
the exhaust includes a tank having an internal space maintainable at a negative pressure with respect to the gas-diffusion compartment, and
the circuitry is configured to connect the gas-diffusion compartment to the tank to perform the gas discharge from the gas-diffusion compartment.

11. The plasma etching apparatus according to claim 10, wherein the tank has a same volume as the gas-diffusion compartment.

12. The plasma etching apparatus according to claim 4, wherein
the exhaust includes a tank having an internal space maintainable at a negative pressure with respect to the gas-diffusion compartment, and
the circuitry is configured to connect the gas-diffusion compartment to the tank to perform the gas discharge from the gas-diffusion compartment.

13. The plasma etching apparatus according to claim 12, wherein the tank has a same volume as the gas-diffusion compartment.

14. The plasma etching apparatus according to claim 5, wherein
the exhaust includes a tank having an internal space maintainable at a negative pressure with respect to the gas-diffusion compartment, and
the circuitry is configured to connect the gas-diffusion compartment to the tank to perform the gas discharge from the gas-diffusion compartment.

15. The plasma etching apparatus according to claim 14, wherein the tank has a same volume as the gas-diffusion compartment.

16. A plasma etching method comprising:
(a) supplying a first gas from a gas box at a first flow rate to generate plasma in a chamber of a plasma etching apparatus; and
(b) stopping supply of the first gas from the gas box, supplying a second gas from the gas box at a second flow rate, and performing gas discharge from a gas-diffusion compartment that is configured to diffuse gas from the gas box inside the gas-diffusion compartment and introduce the gas into the chamber,
wherein (b) includes setting the gas-diffusion compartment at a pressure at which the plasma is maintained in the chamber.

17. The plasma etching method according to claim 16, further comprising:
(c) stopping the gas discharge from the gas-diffusion compartment after (b); and
(d) continuously supplying the second gas from the gas box at a third flow rate lower than the second flow rate,
wherein (c) and (d) include setting the gas-diffusion compartment at a pressure at which the plasma is maintained in the chamber.

18. The plasma etching method according to claim 17, wherein the second flow rate is a sum of the third flow rate and an exhaust flow rate at which the gas discharge from the gas-diffusion compartment is performed in (b).
